(19) United States
(12) Patent Application Publication
(10) Pub. No.: US 2026/0159723 A1
(43) Pub. Date: Jun. 11, 2026

(54) RADIATION RAPID SETTING OR CURING POLYSILOXANE COMPOSITION

(71) Applicant: ETERNAL MATERIALS CO., LTD., KAOHSIUNG (TW)

(72) Inventors: YU TING TSENG, KAOHSIUNG (TW); HSIN HUNG CHEN, KAOHSIUNG (TW); YU PING CHEN, KAOHSIUNG (TW); YI CHING PAN, KAOHSIUNG (TW)

(73) Assignee: ETERNAL MATERIALS CO., LTD., KAOHSIUNG (TW)

(21) Appl. No.: 19/384,337

(22) Filed: Nov. 10, 2025

(30) Foreign Application Priority Data
Dec. 9, 2024 (TW) 113147651

(51) Int. Cl. C09D 183/04; C08G 77/00; C08G 77/12; C08G 77/20

(52) U.S. Cl. CPC C09D 183/04; C08G 77/12; C08G 77/20; C08G 77/80

(57) ABSTRACT

A radiation rapid setting or curing polysiloxane composition, including: (A) an organopolysiloxane having two or more alkenyl groups, (B) an organohydrogenpolysiloxane having two or more SiH groups, (C) an organic cross-linking agent having two or more alkenyl groups, and (D) a photoactive catalyst, wherein the refractive index (N_{c}) of the component (C) has the following relationship with the refractive index (N_{ab}) of a mixture of the components (A) and (B):|N_{c}−N_{ab}|≤0.1. Also, a method for manufacturing an encapsulating material.

### FIELD OF THE INVENTION

### Cross Reference to Related Applications

The present application claims priority to Taiwanese Patent Application No. 113147651 filed on 9 Dec. 2024. The content of the application is incorporated herein by reference in its entirety.

The present invention relates to a radiation rapid setting or curing polysiloxane composition and related use thereof.

### BACKGROUND OF THE INVENTION

Semiconductor encapsulating materials must have the characteristics of resistance to high temperature and even resistance to high temperature and high humidity, and even maintain their appearance and optical properties in such environments. Since the optical properties of polysiloxane do not change much even in high-temperature or high-temperature and high-humidity environments, and its overall performance is better than that of epoxy resin, the industry is gradually shifting from using epoxy resin to using polysiloxane as the encapsulating material.

At present, the widely used polysiloxane encapsulating materials are thermosetting ones. Their curing conditions require temperatures greater than 120° C., and it takes more than 2 hours for curing. In order to prevent the encapsulating material from flowing on the substrate and causing overflowing during such long-time baking process, the packaging technology of Dam & Fill (also known as Dam & Filling) has been used in the past. This technology involves first applying a circle of high-viscosity dam material around the component to be packaged to form a barrier wall, and then filling a low-viscosity and flowable encapsulating material within the area enclosed by the barrier wall. However, under such high-temperature and long-time thermal curing conditions, the substrate is prone to shrinkage, warping or even damage, making it impossible to proceed with subsequent processes.

In order to simplify the process steps and reduce material costs, the industry is developing a packaging method that involves mold filling or dispensing the encapsulating material, followed by leveling and curing, as a replacement for the Dam & Fill process. In this method, after applying the encapsulating material, another substrate (referred to as the upper substrate, generally made of a light-transmissive material such as glass or acrylic) with a surface coated with a release layer (formed by a release agent) is applied to the encapsulating material to achieve a leveling effect. Then, after the encapsulating material is cured, the upper substrate is removed (referred to as lift off) to obtain a flat encapsulating material. This method requires that the encapsulating material can be cured rapidly enough during the curing process to prevent it from flowing on the substrate and causing overflowing, while allowing better accuracy and flatness in film thickness and appearance. This method is particularly suitable for encapsulating light-emitting elements, since, in contrast to other semiconductor components, light-emitting elements such as LEDs (including inorganic LEDs, OLEDs, Mini LEDs, Micro LEDs, etc.) place additional demands on the encapsulating material in terms of good flatness and light transmittance. Therefore, the encapsulating material used for light-emitting elements such as LEDs should be able to withstand high-temperature or high-temperature and high-humidity environments, have good optical transmission, have good flatness (for example, no ripples on the surface), and not be prone to yellowing, etc.

In order to achieve the rapid curing described above, the radiation curing method may be used. However, at present, most of the polysiloxane addition-type curing systems for radiation curing (e.g., UV curing) are of the delayed type. That is, after being irradiated with UV light, the systems remain in a flowable liquid state or semi-solid state, which require further thermal curing (referred to as post-baking) allow the encapsulating material to set (i.e., become non-flowable) and cure. If the encapsulating material is to be set or cured immediately after UV light irradiation, a large amount of metal catalyst (e.g., platinum catalyst) needs to be added. However, apart from increasing the process cost, this will cause the encapsulating material to be prone to yellowing at high temperature, resulting in poor optical properties and failing to meet the product property requirements.

In response to the above-described technical problems, the industry expects to develop encapsulating materials that can be rapidly set or cured by radiation, have good thermal stability and have good optical properties.

### SUMMARY OF THE INVENTION

The present invention provides a radiation rapid setting or curing polysiloxane composition, including:
(A) an organopolysiloxane having two or more alkenyl groups,
(B) an organohydrogenpolysiloxane having two or more SiH groups,
(C) an organic cross-linking agent having two or more alkenyl groups, and
(D) a photoactive catalyst,
wherein the refractive index (N_{c}) of the component (C) has the following relationship with the refractive index (N_{ab}) of a mixture of the components (A) and (B):

$$\vert {N}_{c} - {N}_{a b} \vert \leq 0. 1 .$$

The present invention also provides a two-component composition, including a combination of component (I) and component (II), wherein the component (I) includes component (A), component (C) and component (D), and the component (II) includes component (B).

The present invention also provides a method for manufacturing a encapsulating material, including irradiating the composition with radiation (such as UV light) to rapidly set or cure the composition.

In order to make the above objectives, technical features and advantages of the present invention more obvious and easier to understand, a detailed description is provided below with some specific examples.

### DETAILED DESCRIPTION OF THE INVENTION

In order to facilitate the understanding of the disclosure set forth herein, several terms are defined below.

The term “rapid setting or curing” is defined in the present invention as a encapsulating material being capable of being set (i.e., become non-flowable) or cured within 10 minutes.

The term “refractive index” means the ratio of the velocity of light in vacuum to its phase velocity after entering a medium. The refractive index of vacuum is 1.

The term “transmission” refers to the amount of light passing through a medium (e.g., polysiloxane resin) divided by the total amount of incident light.

The term “nonlinear” means branched, network-like, dendritic, star-shaped, cascade-like or other shapes that are not linear.

The term “alkyl group” refers to a saturated linear or branched hydrocarbon group typically having 1 to 20 carbon atoms (but not limited thereto), preferably having 1 to 6 carbon atoms, more preferably having 1 to 4 carbon atoms, most preferably having 1 to 3 carbon atoms. Examples thereof include (but are not limited to): a methyl group, an ethyl group, an n-propyl group, an isopropyl group, an n-butyl group, an isobutyl group, a tert-butyl group, an n-pentyl group, a neopentyl group, an n-hexyl group, and the like.

The term “aryl group” refers to, for example, a monocyclic, bicyclic or tricyclic aromatic carbocyclic group, preferably having 6 to 20 ring carbon atoms. Examples thereof include (but are not limited to): a phenyl group, an indenyl group, a naphthyl group, a fluorenyl group, an anthracenyl group, a phenanthryl group, and the like. Unless otherwise specified, in the present invention, the “aryl group” may be substituted or unsubstituted. Substituents include, for example, but are not limited to: a halogen, a hydroxyl group, an alkyl group, and the like.

The term “heterocyclic group” refers to a saturated, partially saturated (e.g., named with prefixes such as dihydro, trihydro, tetrahydro, hexahydro) or unsaturated 3- to 14-membered, preferably 4- to 10-membered, more preferably 5- or 6-membered cyclic group consisting of carbon atoms and at least one heteroatom selected from N, O or S, preferably having 1 to 4 heteroatoms, more preferably having 1 to 3 heteroatoms. The heterocyclic group may be a monocyclic, bicyclic or tricyclic ring system, including a fused ring (e.g., a fused ring formed together with another heterocyclic ring or another aromatic carbocyclic ring). Unless otherwise specified, in the present invention, the “heterocyclic group” may be substituted or unsubstituted. Substituents include, for example, but are not limited to: a halogen, a hydroxyl group, an oxo group, an alkyl group, a hydroxyalkyl group, and the like.

The term “nitrogen-containing heterocyclic group” refers to a 3- to 14-membered heterocyclic group in which at least one ring carbon atom is replaced by an N atom, preferably a 4- to 10-membered nitrogen-containing heterocyclic group, more preferably a 5- or 6-membered nitrogen-containing heterocyclic group. Examples thereof include, but are not limited to: a pyrrolyl group, an imidazolyl group, a pyrazolyl group, a pyrimidinyl group, a triazinyl group, a thiazolyl group, a pyridyl group, an indolyl group, an isoindolyl group, a benzimidazolyl group, a benzothiazolyl group, a quinolyl group, an isoquinolyl group, and the like. Unless otherwise specified, in the present invention, the “nitrogen-containing heterocyclic group” may be substituted or unsubstituted. Substituents include, for example, but are not limited to: a halogen, a hydroxyl group, an oxo group, an alkyl group, a hydroxyalkyl group, and the like.

The term “about” means an acceptable error of a particular value as determined by one of ordinary skill in the art, partially depending on how the value is measured or determined.

Each aspect and each example of the present invention disclosed in this specification may be individually combined with all other aspects and examples of the present invention, encompassing all possible combinations.

The polysiloxane composition of the present invention contains the components (A) to (D) described above, and each component is described below.

### (A) Organopolysiloxane Having Two or More Alkenyl Groups

The component (A) has two or more alkenyl groups bonded to silicon, which may be C₂₋₁₂ alkenyl groups, such as vinyl groups, propenyl groups, allyl groups, butenyl groups, pentenyl groups, hexenyl groups, heptenyl groups, octenyl groups, nonenyl groups, decenyl groups, undecenyl groups or dodecenyl groups, preferably vinyl groups, propenyl groups, allyl groups, and more preferably vinyl groups. In addition to alkenyl groups, the component (A) further includes other groups bonded to silicon, which may be: a C₁₋₁₂ alkyl group, a C₃₋₆ cycloalkyl group, a C₆₋₂₀ aryl group or a C₇₋₂₀ aralkyl group, for example, a methyl group, an ethyl group, a propyl group, an isopropyl group, a butyl group, an isobutyl group, a tert-butyl group, a cyclopropyl group, a cyclobutyl group, a cyclopentyl group, a cyclohexyl group, a pentyl group, a hexyl group, a heptyl group, an octyl group, a nonyl group, a decyl group, an undecyl group, a dodecyl group, a phenyl group, a tolyl group, a xylyl group, a naphthyl group, a benzyl group, a phenylethyl group or a phenylpropyl group, preferably a methyl group, an ethyl group, a cyclohexyl group, a phenyl group and a tolyl group, and more preferably a methyl group, a phenyl group or a combination thereof. In some examples of the present invention, the component (A) may have a small amount of hydroxyl or alkoxy groups bonded to silicon, for example, methoxy or ethoxy groups, within a range that does not hinder the objectives of the present invention.

The molecular structure of the component (A) is not particularly limited and may be linear, branched, linear with partially branched chains, cyclic or three-dimensional network structure. The component (A) may be an organopolysiloxane having such a molecular structure, or a combination of two or more organopolysiloxanes having such a molecular structure.

The (A) organopolysiloxane having two or more alkenyl groups, which has a linear, branched, linear with partially branched chains, cyclic or three-dimensional network structure, of the present invention is represented by the following average composition formula (I):

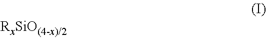

wherein x is a number from 0.8 to 3.0, for example, 0.8, 1, 1.2, 1.5, 1.8, 2, 2.5 or 3; each R may be the same or different and is independently a substituted or unsubstituted monovalent hydrocarbon group, which may be a C₂₋₁₂ alkenyl group, a C₁₋₁₂ alkyl group, a C₃₋₆ cycloalkyl group, a C₆₋₂₀ aryl group or a C₇₋₂₀ aralkyl group, for example, a vinyl group, a propenyl group, an allyl group, a butenyl group, a pentenyl group, a hexenyl group, a heptenyl group, an octenyl group, a nonenyl group, a decenyl group, an undecenyl group, a dodecenyl group, a methyl group, an ethyl group, a propyl group, an isopropyl group, a tert-butyl group, a cyclopropyl group, a cyclobutyl group, a cyclopentyl group, a cyclohexyl group, a phenyl group, a tolyl group, a xylyl group, a naphthyl group, a benzyl group, a phenylethyl group or a phenylpropyl group, and preferably a methyl group, an ethyl group, a cyclohexyl group, a phenyl group and a tolyl group. Preferably, R is a methyl group or a combination of methyl and phenyl groups in addition to the alkenyl groups. According to some embodiments of the present invention, if R is a combination of methyl and phenyl groups in addition to the alkenyl groups, a molar ratio of the methyl group to the phenyl group may be about 9:1, about 8:2, about 7:3, about 6:4, about 5:5, about 4:6, about 3:7, about 2:8 or about 1:9, and is preferably about 2:3.

At least two R groups in each molecule of the component (A) are alkenyl groups (e.g., 2, 3, 4, 5, 6, 7, 8, 9, 10 or more alkenyl groups). As described above, the alkenyl groups may be C₂₋₁₂ alkenyl groups, and preferably vinyl groups. According to some embodiments of the present invention, the alkenyl groups in the component (A) may be bonded to Si at the end of the molecular chain or may be bonded to Si on the side of the molecular chain. The alkenyl group content in the component (A) is about 0.1 mol % to about 40 mol % (e.g., about 0.1 mol %, about 0.5 mol %, about 1 mol %, about 5 mol %, about 10 mol %, about 15 mol %, about 20 mol %, about 25 mol %, about 30 mol %, about 35 mol % or about 40 mol %), and preferably about 0.5 mol % to about 20 mol %, based on the total amount of the R groups.

According to some embodiments of the present invention, the component (A) has a weight-average molecular weight of 100 to 100,000, preferably 200 to 50,000, more preferably 300 to 12,000, and even more preferably 1,000 to 10,000, for example, 100, 150, 200, 300, 500, 1,000, 2,000, 3,000, 4,000, 5,000, 6,000, 10,000, 12,000, 20,000, 50,000 or 100,000.

According to some embodiments of the present invention, the viscosity of the component (A) at 25° C. is preferably in the range of 1 mPa·s to 100,000 mPa·s, and more preferably in the range of 100 mPa·s to 10,000 mPa·s, for example, 1, 10, 100, 1,000, 10,000 or 100,000 mPa·s.

According to some embodiments of the present invention, the amount of the component (A), based on the total weight of solid ingredients of the composition, is 20 weight % to 95 weight %, preferably 30 weight % to 90 weight %, and more preferably 50 weight % to 85 weight %, for example, 25 weight %, 30 weight %, 40 weight %, 50 weight %, 55 weight %, 60 weight %, 65 weight %, 75 weight %, 80 weight %, 85 weight %, 90 weight % or 95 weight %.

The (A) organopolysiloxane having two or more alkenyl groups of the present invention may include SiO_{4/2} units (also referred to as Q units) and/or RSiO_{3/2} units (also referred to as T units) as well as R₃SiO_{1/2} units (also referred to as M units) to form a branched organopolysiloxane. Alternatively, the (A) organopolysiloxane having two or more alkenyl groups may include only R₂SiO_{2/2} units (also referred to as D units) and R₃SiOi₂ units to form a linear organopolysiloxane (also referred to as a straight-chain organopolysiloxane). Alternatively, the (A) organopolysiloxane having two or more alkenyl groups may include only RSiO_{3/2} units, R₂SiO_{2/2} units and R₃SiOi₂ units to form a linear organopolysiloxane with branched chains (also referred to as a partially branched straight-chain organopolysiloxane).

The above-described (A) organopolysiloxane having two or more alkenyl groups represented by average composition formula (I) may include one or more (e.g., 1, 2, 3, 4, 5 or 6) (A) organopolysiloxanes having two or more alkenyl groups to regulate and control the overall properties, each of which may have the following average unit formula (II):

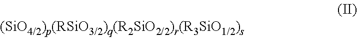

wherein R is as described above, and p, q, r and s satisfy 0≤p<1, 0≤q<1, 0≤r<1, and 0<s<1, but p+q+r>0, and p+q+r+s=1.

In some embodiments of the present invention, the above-described individual (A) organopolysiloxane having two or more alkenyl groups may be represented by the following average unit formulas:
(ViMe₂SiO_{1/2})ₛ(PhSiO_{3/2})_{q}
(ViMe₂SiO_{1/2})ₛ(MeSiO_{3/2})_{q}
(ViMe₂SiO_{1/2})ₛ(PrSiO_{3/2})_{q}
(ViMezSiO_{1/2})ₛ(ViSiO_{3/2})_{q}
(ViMePhSiO_{1/2})ₛ(PhSiO_{3/2})_{q}
(ViMePhSiO_{1/2})ₛ(MeSiO_{3/2})_{q}
(ViMePhSiO_{1/2})ₛ(PrSiO_{3/2})_{q}
(ViMePhSiO_{1/2})ₛ(ViSiO_{3/2})_{q}
(ViMePhSiO_{1/2})_{s′}(ViMe₂SiO_{1/2})_{s″}PhSiO_{3/2})_{q}
(VlMe₂SiO_{1/2})ₛ(Ph₂SiO_{2/2})ᵣ(PhSiO_{3/2})_{q}
(ViMePhSiO_{1/2})ₛ(Ph2SiO_{2/2})ᵣ(PhSiO_{3/2})_{q}
(VlMe₂SiO_{1/2})ₛ(MCPhSiO_{2/2})ᵣ(PhSiO_{3/2})_{q}
(ViMePhSiO_{1/2})ₛ(MePhSiO_{2/2})ᵣ(PhSiO_{3/2})_{q}
(ViMePhSiO1_{l/2})_{s′}(ViMe₂SiO_{1/2})_{s″}(Ph₂SiO_{2/2})ᵣ(PhSiO_{3/2})_{q}
(VlMCzSlO_{1/2})ₛ(SiO_{4/2})ₚ(PhSiO_{3/2})_{q}
(ViMe₂SiO_{1/2})S(SiO_{4/2})ₚ
wherein Me is a methyl group, Ph is a phenyl group, Pr is a propyl group, Vi is a vinyl group, p, q, r and s are as described above, 0<s′<1, 0<s″<1, and s′+s″=s;
alternatively, the above-described individual (A) organopolysiloxane having two or more alkenyl groups may be represented by the following chemical formulas:
ViMe₂SiO(Ph₂SiO)ᵤSiMe₂Vi
ViMe₂SiO(Me₂SiO)ᵥSiMe₂Vi
ViMe₂SiO(Ph₂SiO)ᵤ(Me₂SiO)VSiMe₂Vi
ViMePhSiO(Ph₂SiO)ᵤSiMePhVi
ViMe₂SiO(MePhSiO)ᵤSiMe₂Vi
ViMePhSiO(MePhSiO)ᵥSiMePhVi
ViMePhSiO(MePhSiO)ᵥ(Me₂SiO)ᵤSiMePhVi
ViMe₂SiO(ViMeSiO)ᵤ(Me₂SiO)VSiMe₂Vi
Me₃SiO(ViMeSiO)ᵤSiMe₃
ViMePhSiO(Ph₂SiO)ᵤ(MePhSiO)ᵥSiMePhVi
ViMePhSiO(Ph₂SiO)ᵤ(Me₂SiO)ᵥSiMePhVi
wherein Me is a methyl group, Ph is a phenyl group, Vi is a vinyl group, and u and v are each independently an integer from 1 to 200 (e.g., 1, 2, 5, 10, 20, 50, 100, 120, 160, 180 or 200), and preferably from 160 to 180.

The (A) organopolysiloxane having two or more alkenyl groups of the present invention is preferably in a liquid, solid or viscous state at room temperature. If the organopolysiloxane is in a solid state, the viscosity thereof may be adjusted and controlled by adding a solvent so as to facilitate operation. Said solvent may be toluene, hexane, cyclohexane, or the like.

### (B) Organohydrogenpolysiloxane Having Two or More SiH Groups

The molecular structure of the component (B) is not particularly limited and may be straight-chain, branched, partially branched straight-chain, cyclic or three-dimensional network structure, and preferably straight-chains, branched or partially branched straight-chain. The position of the hydrogen atoms bonded to silicon in the component (B) is not limited and may be located at the end or on the side of the molecular chain, or on the branch chain. In addition to hydrogen atoms, the component (B) also includes organic groups bonded to silicon, including but not limited to an alkyl group, an aryl groups, an aralkyl group, and the like.

The polysiloxane composition of the present invention may include one or more (e.g., 1, 2, 3, 4, 5 or 6) (B) organohydrogenpolysiloxanes having two or more SiH groups to regulate and control the overall properties, each of which may have the following average unit formula (III):

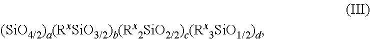

wherein each R^{x} may be the same or different and is each independently H or a monovalent hydrocarbon group without an aliphatic unsaturated carbon bond, including, for example, but not limited to a C₂₋₁₂ alkyl group, for example, a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, an undecyl group or a dodecyl group; a C₃₋₆ cycloalkyl group, for example, a cyclohexyl group or a cyclopentyl group; a C₆₋₂₀ aryl group, for example, a phenyl group, a tolyl group, a xylyl group or a naphthyl group; a C₇₋₂₀ aralkyl group, such as a benzyl group, a phenylethyl group or a phenylpropyl group; and groups in which some or all of the hydrogen atoms in these groups are substituted with a halogen such as fluorine, chlorine, bromine or iodine. Preferably, R^{x} is a methyl group or a combination of methyl and phenyl groups in addition to H. If R^{x} is a combination of methyl and phenyl groups in addition to H, a molar ratio of the methyl group to the phenyl group may be about 9:1, about 8:2, about 7:3, about 6:4, about 5:5, about 4:6, about 3:7, about 2:8 or about 1:9.

In formula (III), a, b, c and d satisfy 0≤a<1, 0≤b<1, 0<c≤1, and 0<d<1, but a+b+c>0, and a+b+c+d=1.

The component (B) as a whole may also be represented by the above-described average unit formula (III).

According to some embodiments of the present invention, at least two R^{x} in each molecule of the component (B) are H (e.g., 2, 3, 4, 5, 6, 7, 8, 9, 10 or more H).

According to some embodiments of the present invention, the component (B) has a weight-average molecular weight of 100 to 100,000, preferably 200 to 50,000, more preferably 300 to 12,000, and even more preferably 1,000 to 10,000, for example, 100, 150, 200, 300, 500, 1,000, 2,000, 3,000, 4,000, 5,000, 6,000, 10,000, 12,000, 20,000, 50,000 or 100,000.

According to some embodiments of the present invention, the amount of the component (B), based on the total weight of solid ingredients of the composition, is 1 weight % to 70 weight %, preferably 10 weight % to 60 weight %, and more preferably 15 weight % to 40 weight %, for example, 1 weight %, 5 weight %, 10 weight %, 15 weight %, 20 weight %, 30 weight %, 40 weight %, 50 weight %, 60 weight % or 70 weight %.

The viscosity of the component (B) at 25° C. is not limited and is preferably in the range of 1 mPa·s to 100,000 mPa·s, and more preferably in the range of 2 mPa·s to 10,000 mPa·s, for example, 1, 2, 10, 100, 1,000, 10,000, or 100,000 mPa·s.

The (B) organohydrogenpolysiloxane having two or more SiH groups of the present invention is preferably in a liquid, solid or viscous state at room temperature. If the organopolysiloxane is in a solid state, the viscosity thereof may be adjusted and controlled by adding a solvent so as to facilitate operation. Said solvent may be toluene, hexane, cyclohexane, or the like.

In some embodiments of the present invention, the above-described individual (B) organohydrogenpolysiloxane having two or more SiH groups may be represented by the following average unit formulas:

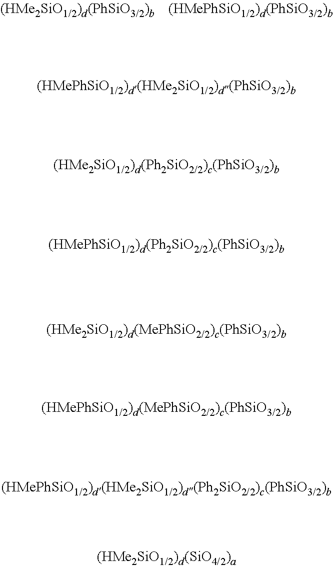

wherein a, b, c and d are as described above, 0<d′<1, 0<d″<1, and d′+d″=d.

Alternatively, the above-described individual (B) organohydrogenpolysiloxane having two or more SiH groups may be represented by the following chemical formulas:

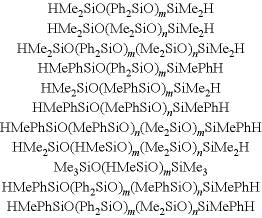

wherein m and n are each independently an integer from 1 to 200 (e.g., 1, 2, 5, 10, 20, 50, 100, 120, 160, 180 or 200), and preferably from 160 to 180.

### (C) Organic Cross-Linking Agent Having Two or More Alkenyl Groups

The (A) organopolysiloxane having two or more alkenyl groups of the present invention may undergo hydrosilylation with the (B) organohydrogenpolysiloxanes having two or more SiH groups, wherein the alkenyl groups are converted to alkyl groups and bonded to the silicon atoms of the SiH groups, and the hydrogen atoms of the SiH groups are removed. In order to promote cross-linking of the polysiloxane and achieve rapid setting or curing, the polysiloxane composition of the present invention further includes (C) an organic cross-linking agent having two or more alkenyl groups.

The inventors of the present invention have found that the refractive index (N_{c}) of the component (C) should have the following relationship with the refractive index (N_{ab}) of a mixture of the components (A) and (B): | N_{c}−N_{ab}|≤0.1, i.e., the absolute value of a difference between N_{c} and N_{ab} should be ≤0.1, preferably ≤0.08, more preferably ≤0.05, and most preferably ≤0.02, for example, ≤0.1, ≤0.09, ≤0.08, ≤0.07, ≤0.06, ≤0.05, ≤0.04, ≤0.03, ≤0.02 or ≤0.01. For example, if the refractive index (N_{ab}) of the mixture of the components (A) and (B) is 1.54, the refractive index (N_{c}) of the component (C) should be between 1.44 and 1.64. When the refractive index (N_{c}) of the component (C) has the above relationship with the refractive index (N_{ab}) of the mixture of the components (A) and (B), they may be uniformly mixed without causing stratification, emulsification or cloudiness. When applied to a radiation curing system (such as UV curing), the curing efficiency is significantly improved, and the surface can become dry and non-sticky in a relatively short time after radiation irradiation, achieving the effect of rapid setting. For example, if the absolute value of the difference between N_{c} and N_{ab} is <0.1, setting or curing may be achieved more rapidly after radiation irradiation. Conversely, if the absolute value of the difference between N_{c} and N_{ab} is >0.1, insufficient cross-linking may occur after radiation irradiation, failing to achieve rapid setting or curing. In addition, the addition of the component (C) helps to form a network structure after curing, enhancing the hardness of the cured product and further improving its physical properties. The inventors of the present invention have further found that the component (C), like the component (A), has alkenyl groups and can undergo hydrosilylation reaction with SiH groups, wherein the (C) organic cross-linking agent having two or more alkenyl groups has the properties of a small molecular structure and a relatively high proportion of alkenyl groups, so that the probability of reaction occurrence may be increased, thereby increasing the reaction rate of UV curing and reducing the UV curing reaction temperature.

The (C) organic cross-linking agent having two or more alkenyl groups of the present invention has two or more alkenyl groups, for example, 2, 3, 4, 5, 6 or 8. The (C) organic cross-linking agent having two or more alkenyl groups of the present invention has a core structure, and the core structure is modified by two or more alkenyl groups.

According to some embodiments of the present invention, the above-described core structure may be a polyvalent organic structure based on a hydrocarbon group or a heterocyclic group, and the above-described hydrocarbon group optionally contains one or more oxygen atoms. The valence of the core structure corresponds to the number of alkenyl groups that modify the core structure described above. Preferably, the above-described core structure may be a divalent organic structure, a trivalent organic structure or a tetravalent organic structure. In the present invention, a polyvalent heterocyclic group, taking a divalent heterocyclic group as an example, refers to an atomic group remaining after removing two hydrogen atoms directly bonded to carbon atoms or heteroatoms on a heterocyclic ring.

According to some embodiments of the present invention, the above-described alkenyl groups may be connected to the core structure via a linking group. The linking group may be a single bond, —O—, —S—, —C(O)—, —C(O)O—, —OR¹—, —SR¹—, —C(O)R¹— or —C(O)OR¹—, wherein R¹ is a C₁₋₆ alkylene group or a C₁₋₆ alkyleneoxy group, preferably a C₁₋₄ alkylene group or a C₁₋₄ alkyleneoxy group, and more preferably a C₁₋₂ alkylene group or a C₁₋₂ alkyleneoxy group; and preferred linking groups may be —O—, —C(O)—, —C(O)O— or —OR¹—. Said linking group may be connected to the core structure in any direction. Taking —C(O)O— as an example, the direction in which the linking group is connected to the core structure may be represented by * as follows: —C(O)O—* or *—C(O)O—.

Embodiments of the above alkenyl group may be a C₂₋₆ alkenyl group or a C₃₋₈ cycloalkenyl group, for example, a vinyl group, a propenyl group (e.g., an allyl group, an 1-propenyl group, an isopropenyl group), a butenyl group, a pentenyl group, a hexenyl group or a cyclohexenyl group, preferably a vinyl group or a propenyl group, and more preferably an allyl group or an isopropenyl group.

According to some embodiments of the present invention, the (C) organic cross-linking agent having two or more alkenyl groups of the present invention may have the following formula:

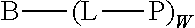

wherein
B serves as a core structure and is a polyvalent organic group with a valence of w;
L is a linking group, defined as previously described herein;
P is an alkenyl group, defined as previously described herein; and
w is an integer selected from 2 to 8, for example, 2, 3, 4, 5, 6, 7 or 8, preferably an integer from 2 to 6, and more preferably an integer from 2 to 4.

According to some embodiments of the present invention, B may be a polyvalent hydrocarbon group or heterocyclic group; the above-described hydrocarbon group optionally contains one or more oxygen atoms; and the above-described heterocyclic group is optionally substituted with 1 to 3 groups selected from a halogen, a hydroxyl group, an oxo group, an alkyl group and a hydroxyalkyl group. According to still some embodiments of the present invention, the above-described polyvalent hydrocarbon group may be a polyvalent aliphatic hydrocarbon group (e.g., C₁₋₂₀ aliphatic hydrocarbon group) or aromatic hydrocarbon group (e.g., C₆₋₂₀ aromatic hydrocarbon group); and the above-described polyvalent heterocyclic group may be a 3- to 14-membered heterocyclic group, including, for example, but not limited to: a pyrrolyl group, an imidazolyl group, a pyrazolyl group, a pyrimidinyl group, a triazinyl group, a thiazolyl group, a pyridyl group, an indolyl group, an isoindolyl group, a benzimidazolyl group, a benzothiazolyl group, a quinolyl group or an isoquinolyl group. According to some embodiments of the present invention, B may be an alkyl group, an alkoxy group, a phenyl group, a biphenyl group, a segment derived from a polyol (e.g., polyethylene glycol or polypropylene glycol), or a 3- to 14-membered heterocyclic group optionally substituted with 1 to 3 groups selected from a halogen group, a hydroxyl group, an oxo group, an alkyl group and a hydroxyalkyl group.

In some embodiments, examples of the polyvalent organic group B include, for example, but are not limited to:

### Divalent Organic Groups

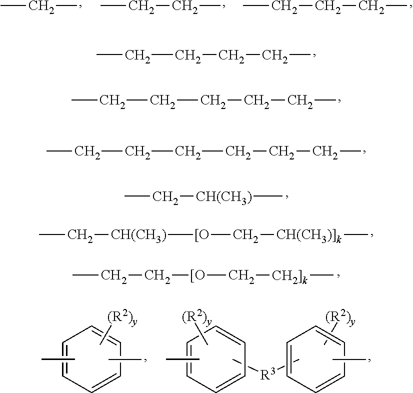

wherein k is an integer from 1 to 10, each R₂ may be the same or different and is each independently H, a C₁-C₄ alkyl group, a C₁-C₄ perfluoroalkyl group, a C₁-C₄ alkoxy group or a halogen, R₃ is a covalent bond, —O—, —S—, —CH₂—, —S(O)₂—, —C(CF₃)₂— or —C(CH₃)₂—, and each y is independently an integer from 0 to 4;

### Trivalent Organic Groups

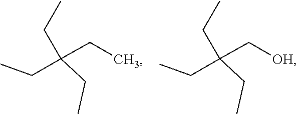

or a trivalent heterocyclic group selected from a pyrimidinyl group, a triazinyl group, a pyridyl group and an isoindolyl group, wherein the trivalent heterocyclic group described above is optionally substituted with 1 to 3 groups selected from an oxo group, an alkyl group and a hydroxyalkyl group;

### Tetravalent Organic Groups

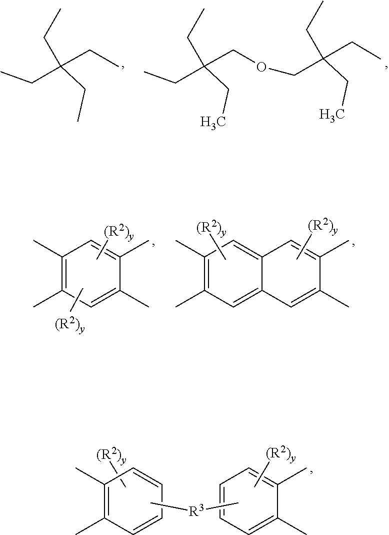

wherein each R₂ may be the same or different and is each independently H, a C₁-C₄ alkyl group, a C₁-C₄ perfluoroalkyl group, a C₁-C₄ alkoxy group or a halogen, R₃ is a covalent bond, —O—, —S—, —CH₂—, —S(O)₂—, —C(CF₃)₂— or —C(CH₃)₂—, and each y is independently an integer from 0 to 4; and

### Hexavalent Organic Group

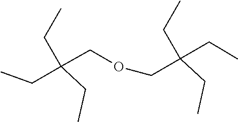 [SMILES: CCC(CC)(CC)COCC(CC)(CC)CC]

According to some embodiments of the present invention, exemplary-linking group-alkenyl group (i.e., -L-P) structures are listed as follows:

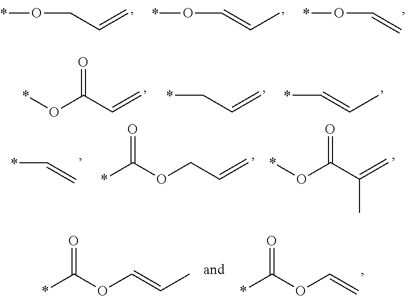

wherein * indicates the direction of connection to the core structure. Specific examples of the (C) organic cross-linking agent having two or more alkenyl groups may include (but are not limited to): triallyl isocyanurate (TAIC), tris(2-hydroxyethyl)isocyanurate triacrylate, diallyl phthalate, diallyl isophthalate, diallyl terephthalate, tetraallyl pyromellitate, 1,6-hexanediol diacrylate, ethylene glycol dimethacrylate, tri(propylene glycol)diacrylate, ethoxylated bisphenol A diacrylate, trimethylolpropane triacrylate, ethoxylated trimethylolpropane triacrylate, dipentaerythritol hexaacrylate, pentaerythritol triacrylate, pentaerythritol tetraacrylate, di(trimethylolpropane)tetraacrylate, or a combination thereof.

According to some embodiments of the present invention, the (C) organic cross-linking agent having two or more alkenyl groups does not contain an alkynyl group, or the (C) organic cross-linking agent having two or more alkenyl groups does not contain a silicon atom (i.e. does not contain a silicon-containing group such as siloxane or a SiH group). According to a preferred embodiment of the present invention, the (C) organic cross-linking agent having two or more alkenyl groups contains neither an alkynyl group nor a silicon atom. Although the alkynyl group may undergo hydrosilylation reaction with a SiH group, they may reduce the reaction rate.

According to some embodiments of the present invention, the component (C) has a weight-average molecular weight of 100 to 1,500, preferably 100 to 1,000, and more preferably 200 to 500, for example, 100, 200, 300, 400, 500, 600, 700, 800, 900, 1,000, 1,200 or 1,500. According to some embodiments of the present invention, the component (C) has a weight-average molecular weight smaller than that of the component (A).

According to some embodiments of the present invention, the amount of the component (C), based on the total weight of solid ingredients of the composition, is 0.05 weight % to 10 weight %, preferably 0.1 weight % to 5 weight %, and more preferably 0.2 weight % to 3 weight %, for example, 0.05 weight %, 0.1 weight %, 0.2 weight %, 0.3 weight %, 0.4 weight %, 0.5 weight %, 0.6 weight %, 0.7 weight %, 0.8 weight %, 0.9 weight %, 1 weight %, 1.2 weight %, 1.5 weight %, 1.8 weight %, 2 weight %, 3 weight %, 4 weight %, 5 weight %, 6 weight %, 7 weight %, 8 weight %, 9 weight % or 10 weight %. When the amount of the component (C) is too low, the rapid curing effect may not be achieved, and a longer irradiation time (e.g., UV) may be required to fully cure the resin. When the amount of the component (C) is too high, the light transmittance may decrease, and the high-temperature stability of the resin may be affected (i.e., the light transmittance decreases after high-temperature test).

The amounts of the components (A), (B) and (C) in the present invention should be determined in consideration of the total number of moles of the alkenyl groups contained in the components (A) and (C) and the total number of moles of the SiH groups contained in the component (B), wherein a ratio of the total number of moles of the alkenyl groups to the total number of moles of the SiH groups should range from 0.1 to 4, preferably from 0.5 to 3, and more preferably from 0.7 to 1, for example, 0.1, 0.2, 0.3, 0.4, 0.5, 0.6, 0.7, 0.8, 0.9, 1, 1.1, 1.2, 1.3, 1.4, 1.5, 2, 2.5, 3, 3.5 or 4. Unreacted alkenyl groups or SiH groups may adversely affect the long-term stability of the resin. Therefore, in some preferred embodiments of the present invention, the total number of moles of the alkenyl groups/the total number of moles of the SiH groups is preferably close to 0.7 to 1.

Both of the components (A) and (B) of the present invention have a polysiloxane structure, are highly compatible with each other, and have a refractive index of about 1.35 to 1.65, which varies with the type of R and R^{x}. If R and R^{x} of the components (A) and (B) are primarily or exclusively alkyl groups (e.g., methyl), the refractive index of both is between about 1.40 and 1.50 (lower refractive index). If R and R^{x} of the components (A) and (B) are primarily or exclusively phenyl groups unsubstituted or substituted with one or more C₁₋₃ alkyl groups (e.g., phenyl), the refractive index of both is between about 1.45 and 1.60 (higher refractive index).

### (D) Photoactive Catalyst

The (D) photoactive catalyst of the present invention is a catalyst that may be activated under light irradiation at 200-500 nm and is capable of catalyzing hydrosilylation reaction. It is preferably a catalyst of a metal element, a salt or complex thereof, more preferably a catalyst of a Group VIIIB transition metal (including nickel, palladium, platinum and rhodium, etc.) element, a salt or complex thereof, and most preferably a catalyst of a platinum element, a salt or complex thereof. The (D) photoactive catalyst of the present invention may be a pure catalyst material or a catalyst material deposited on a carrier (e.g., silica or carbon black). In some preferred embodiments, the (D) photoactive catalyst of the present invention is soluble or dispersible in an organic phase, facilitating thorough mixing with other components.

Photoactivation means that when the catalyst absorbs photons greater than or equal to the band gap energy, it converts from a ground state to an excited state to form highly active species and undergo redox reaction with other substances. Therefore, the photoactive catalyst will be activated and exert its catalytic effect during the radiation curing process.

According to some embodiments of the present invention, the types of the (D) photoactive catalyst include platinum complexes of cyclopentadiene, cyclooctadiene, norbornadiene or β-diketone. Specific species may be listed as follows (but not limited to): a (cyclopentadienyl)dimethyl platinum complex, a (cyclopentadienyl)trimethyl platinum complex, a (methylcyclopentadienyl)trimethyl platinum complex, a (cyclopentadienyl)ethyldimethyl platinum complex, a (cyclopentadienyl)acetyldimethyl platinum complex, a (methylcyclopentadienyl)diethyl platinum complex, a (methylcyclopentadienyl)trihexyl platinum complex, a (trimethylsilylcyclopentadienyl)diphenyl platinum complex, a (trimethylsilylcyclopentadienyl)trimethyl platinum complex, a (dimethylphenylsilylcyclopentadienyl)triphenyl platinum complex, a (cyclopentadienyl)dimethyltrimethylsilylmethyl platinum complex, a (1,5-cyclooctadiene)dimethyl platinum complex, a (1,5-cyclooctadiene)diphenyl platinum complex, a (1,5-cyclooctadiene)dipropyl platinum complex, a (methylcycloocta-1,5-dienyl)diethyl platinum complex, a (2,5-norbornadiene)dimethyl platinum complex, a (2,5-norbornadiene)diphenyl platinum complex, and a combination thereof.

According to some embodiments of the present invention, the amount of the (D) photoactive catalyst of the present invention, based on the total weight of solid ingredients of the composition, is 1 ppm to 50 ppm, preferably 5 ppm to 25 ppm, and more preferably 8 ppm to 15 ppm, for example, 1 ppm, 2 ppm, 3 ppm, 4 ppm, 5 ppm, 6 ppm, 7 ppm, 8 ppm, 9 ppm, 10 ppm, 12 ppm, 15 ppm, 18 ppm, 20 ppm, 30 ppm, 40 ppm or 50 ppm. It is expected that the higher the amount of the catalyst used, the faster the reaction rate. However, excessive catalyst addition leads to increased costs, and deteriorates the transmittance of the polysiloxane resin (e.g., <90%) and increases the yellowing coefficient. The polysiloxane composition of the present invention may achieve the rapid setting or curing effect with a lower content of the catalyst. Therefore, compared with the prior art, it has a cost advantage and may endow the polysiloxane resin with good optical properties.

### Polysiloxane Resin

The components involved in the hydrosilylation reaction of the present invention are the above-described (A) organopolysiloxane having two or more alkenyl groups, (B) organohydrogenpolysiloxane having two or more SiH groups, (C) organic cross-linking agent having two or more alkenyl groups, and (D) photoactive catalyst, wherein the (D) photoactive catalyst is activated under radiation irradiation and catalyzes the hydrosilylation reaction to form a polysiloxane resin. The above-described radiation curing is a process of converting the composition from a liquid or flowable state to a solid state by irradiation energy. The form of radiation includes an electron beam or UV light.

In the case of UV curing, UV light may be divided into near ultraviolet (UVA), far ultraviolet (UVB), and ultra-short ultraviolet (UVC) according to the wavelength, and the radiation dose is generally in the range of 1,000 to 10,000 mJ/cm², and preferably 1,500 to 5,000 mJ/cm², for example, 1,000 mJ/cm², 1,500 mJ/cm², 2,000 mJ/cm², 3,000 mJ/cm², 4,000 mJ/cm², 5,000 mJ/cm², 6,000 mJ/cm², 7,000 mJ/cm², 8,000 mJ/cm², 9,000 mJ/cm² or 10,000 mJ/cm². To achieve rapid setting or curing, the UV light irradiation time should be within 10 minutes, for example, 0.5 minutes, 1 minute, 1.5 minutes, 2 minutes, 3 minutes, 3.5 minutes, 4 minutes, 5 minutes, 6 minutes, 7 minutes, 8 minutes, 9 minutes or 10 minutes. According to some embodiments of the present invention, a near ultraviolet (UVA) light source with an irradiation intensity of 2,000 mJ/cm² is used in the present invention.

After the radiation irradiation is completed, the catalyst in the polysiloxane resin still has catalytic activity, so the hydrosilylation reaction may be continuously performed to further cure the resin. If necessary, post-baking may also be applied to further cure the resin, but the conditions of post-baking, such as temperature and time, should not cause the substrate to shrink or warp. Since the polysiloxane resin of the present invention may be rapidly set or cured under radiation irradiation, it has good processability during subsequent operations (e.g., moving samples into an oven) and may reduce or avoid resin overflow.

According to the present invention, the process of radiation irradiation may increase the temperature of the composition, but the temperature of the composition is still lower than that of the one undergoing reaction through thermal curing or the one undergoing radiation irradiation first and then thermal curing. Generally, the temperature of thermal curing reaction should reach more than 120° C., and the curing time should reach more than 2 hours to achieve effective curing. For the one undergoing radiation irradiation first and then thermal curing, the temperature of thermal curing reaction should reach more than 80° C., and the curing time should reach more than 0.5 hours. However, as described above, high-temperature and long-term thermal curing conditions easily cause shrinkage, warping or even damage of the substrate, which thus does not meet the product and process requirements of the present invention. In contrast, the temperature reached by the radiation curing of the present invention does not exceed 80° C., and the curing time is shorter.

The polysiloxane resin formed after curing the composition of the present invention may be used for packaging light-emitting elements such as LEDs, but should not be limited thereto. The polysiloxane resin of the present invention has the properties of good flatness, good optical penetration, resistance to yellowing, high-temperature stability, and the like. In some embodiments of the present invention, the polysiloxane resin of the present invention has a light transmittance of at least 90%, at least 92%, at least 95% or at least 98% and still has a light transmittance of at least 90%, at least 92%, at least 95% or at least 98% after high-temperature test (e.g., baking at 150° C. for 24 hours). In some embodiments of the present invention, the polysiloxane resin of the present invention has a low yellowness index, for example, less than 5, less than 4, less than 3 or less than 2. In some embodiments of the present invention, the polysiloxane resin of the present invention has a low average surface roughness, for example, up to 0.05 μm, up to 0.04 μm, up to 0.03 μm or up to 0.02 μm. The compositions of the present invention may achieve good flatness through the above-described leveling and curing packaging method.

The present invention also provides a two-component composition, including a combination of component (I) and component (II), wherein the component (I) includes component (A), component (C) and component (D), and the component (II) includes component (B). By storing the component (B) separately, the alkenyl groups and SiH groups have no chance of contact, thus avoiding spontaneous reaction. The polysiloxane resin may be prepared by mixing the component (I) and the component (II).

According to some embodiments of the present invention, the composition may include other optional materials well known in formulation technology, such as an antioxidant, a hindered amine light stabilizer, a UV light absorber and stabilizer, a surfactant, a flow control agent, a thixotropic agent, a filler, an organic solvent, a mildew inhibitor and other conventional auxiliaries.

### EXAMPLES

The following examples are intended to further illustrate the present invention but are not intended to limit the scope of the present invention. Any modifications and changes readily achievable by those of ordinary knowledge in the art are included within the scope of the disclosure of this specification and the appended claims.

The description of the ingredients used in each of the examples and comparative examples is shown in Table 1:

TABLE 1
Ingredient

(A-1) Me_{0.62}Vi_{0.31}Ph_{0.91}SiO_{1.08}, viscosity: about 4,000 mPa · s,
Ph = 49.4 mol %, Vi = 16.8 mol % (weight-average molecular weight: about 900)
(A-2) Me_{2.00}Vi_{0.01}SiO_{0.99}, viscosity: about 500 mPa · s, Me = 99.5 mol %,
Vi = 0.5 mol % (weight-average molecular weight: about 27,000)
(B-1) HMe₂SiO(Ph₂SiO)SiMe₂H
(B-2) Me₃SiO(HMeSiO)ₘ(Me₂SiO)ₙSiMe₃; m: 160 to 180, n: 160 to 180
(C) triallyl isocyanurate, diallyl phthalate or tetraallyl pyromellitate
(D) (methylcyclopentadienyl)trimethyl platinum complex

According to the compositions and amounts used shown in Table 2 below, the ingredients (A) to (D) were added to a 5-liter reactor and stirred at room temperature for 1 hour to prepare the compositions of Examples 1 to 8 and Comparative Examples 1 to 4. The compositions of the examples and comparative examples in the present invention were coated onto glass substrates and irradiated with UV light for different lengths of time to obtain cured products (polysiloxane resins). Subsequently, the physical properties of the polysiloxane compositions and polysiloxane resins, including the refractive index, light transmittance and thermal stability, were measured with the following test methods.

### 1. Refractive Index

The refractive index of the sample (e.g., a homogeneous mixture of the components (A) and (B) or individual component (C)) was measured at 25° C. using an Abbe refractometer from ATAGO Company, with visible light at a wavelength of 589 nm as the light source used for measurement.

### 2. UV Curing State

The composition was irradiated with a UVA light source at an energy of 2,000 mJ/cm². The time required for the composition to react until it was set or cured was recorded, and whether the surface of the colloid exhibited non-stickiness was observed.

3. Light Transmittance and Light Transmittance after High Temperature Test

After radiation curing, the initial light transmittance was tested using a HunterLab spectrophotometer. The sample was then aged in a 150° C. oven for 24 hours, and the light transmittance was tested again to observe changes in transmittance at a wavelength of 450 nm.

Tables 2 and 3 list the amounts of the components used in the preparation of the above-described examples and comparative examples, reaction conditions and test results:

TABLE 2

| | | Example | Example | Example | Example | Example | Example | Example | Example |
|---|---|---|---|---|---|---|---|---|---|
| | | 1 | 2 | 3 | 4 | 5 | 6 | 7 | 8 |
| (A-1) | Weight (g) | 80 | 80 | 80 | | | 81.5 | 76.5 | 67 |
| Substance | | | | | | | | | |
| (A-2) | Weight (g) | | | | 85 | 85 | | | |
| Substance | | | | | | | | | |
| (B-1) | Weight (g) | 19 | 19 | 19 | | | 18 | 20.5 | 25 |
| Substance | | | | | | | | | |
| (B-2) | Weight (g) | | | | 14 | 14 | | | |
| Substance | | | | | | | | | |
| (C) Triallyl | Weight (g) | 1 | | | | | 0.5 | | |
| isocyanurate | | | | | | | | | |
| (C) Diallyl | Weight (g) | | 1 | | 1 | | | 3 | 8 |
| phthalate | | | | | | | | | |
| (C) Tetraallyl | Weight (g) | | | 1 | | 1 | | | |
| pyromellitate | | | | | | | | | |
| (D) (Methyl- | Weight | 10 | 10 | 10 | 10 | 10 | 10 | 10 | 10 |
| cyclopentadienyl) | (ppm) | | | | | | | | |
| trimethyl | | | | | | | | | |
| platinum | | | | | | | | | |
| complex | | | | | | | | | |

| | | | | | | | | |
|---|---|---|---|---|---|---|---|---|
| N_{ab} | 1.54 | 1.54 | 1.54 | 1.41 | 1.41 | 1.54 | 1.54 | 1.54 |
| N_{c} | 1.52 | 1.46 | 1.48 | 1.46 | 1.48 | 1.52 | 1.46 | 1.46 |
| \| N_{c} − N_{ab} \| | 0.02 | 0.08 | 0.06 | 0.05 | 0.07 | 0.02 | 0.08 | 0.08 |
| Total number of moles of | 1.0 | 1.0 | 1.0 | 0.7 | 0.7 | 1.0 | 1.0 | 1.0 |
| alkenyl groups in | | | | | | | | |
| components (A) and | | | | | | | | |
| (C)/total number of moles | | | | | | | | |
| of SiH groups in | | | | | | | | |
| component (B) | | | | | | | | |
| UV irradiation time (min) | 0.5 | 5 | 3 | 1.5 | 3.5 | 2 | 3 | 4 |
| State after UV irradiation | Set/ | Set/ | Set/ | Set/ | Set/ | Set/ | Set/ | Set/ |
| | cured | cured | cured | cured | cured | cured | cured | cured |
| Light transmittance | >95% | >95% | >95% | >95% | >95% | >95% | >95% | >93% |
| Light transmittance after | >95% | >95% | >95% | >95% | >95% | >95% | >90% | >90% |
| high-temperature test | | | | | | | | |

TABLE 3

| | | Comparative | Comparative | Comparative | Comparative |
|---|---|---|---|---|---|
| | | Example 1 | Example 2 | Example 3 | Example 4 |
| (A-1) Substance | Weight (g) | 82.5 | 82.5 | | 59 |
| (A-2) Substance | Weight (g) | | | 85 | |
| (B-1) Substance | Weight (g) | 17.5 | 17.5 | | 29 |
| (B-2) Substance | Weight (g) | | | 14 | |
| (C) Triallyl isocyanurate | Weight (g) | | | 1 | |
| (C) Diallyl phthalate | Weight (g) | | | | 12 |
| (C) Tetraallyl | Weight (g) | | | | |
| pyromellitate | | | | | |
| (D) | Weight (ppm) | 10 | 30 | 10 | 10 |
| (Methylcyclopentadienyl) | | | | | |
| trimethyl platinum | | | | | |
| complex | | | | | |

| | | | | |
|---|---|---|---|---|
| N_{ab} | 1.54 | 1.54 | 1.41 | 1.54 |
| N_{c} | — | — | 1.52 | 1.46 |
| \| N_{c} − N_{ab} \| | — | — | 0.11 | 0.08 |
| Total number of moles of alkenyl groups | 1.0 | 1.0 | 0.7 | 1.0 |
| in components (A) and (C)/total number | | | | |
| of moles of SiH groups in component | | | | |
| (B) | | | | |
| UV irradiation time (min) | >10 | >10 | >10 | 4 |
| State after UV irradiation | Not set | Set/cured | Not set | Set/cured |
| Light transmittance | >95% | >95% | <90% | >90% |
| Light transmittance after high- | >95% | <90% | <90% | <90% |
| temperature test | | | | |

It could be seen from Table 2 that in Example 1 to Example 8, |N_{c}−N_{ab}|≤0.1. These compositions achieve a set or cured state within 10 minutes of UV light irradiation (requiring a maximum of only 4 minutes of UV light irradiation as a whole). It was also observed that the smaller the |N_{c}−N_{ab}|, the shorter the UV light irradiation time required for setting or curing. In addition, Example 1 to Example 8 exhibited good optical properties and thermal stability. In contrast, it could be seen from Table 3 that the composition of Comparative Example 1 was not added with the component (C) and failed to satisfy the condition of |N_{c}−N_{ab}|≤0.1, resulting in insufficient cross-linking. Even after more than 10 minutes of UV light irradiation, the composition was still not set. The composition of Comparative Example 2 was also not added with the component (C), but the amount of the component (D) was increased to 3 times the normal amount (i.e., 30 ppm). After more than 10 minutes of UV light irradiation, the composition reached a set or cured state, but in this comparative example, an excessive amount of platinum catalyst was added, resulting in increased costs and poor thermal stability (the light transmittance decreased to <90% after high-temperature test, and yellowing occurred). Although the composition of Comparative Example 3 was added with the component (C), |N_{c}−N_{ab}|>0.1. Even after more than 10 minutes of UV light irradiation, the composition was still not set, and the optical properties were poor. In addition, under the condition of |N_{c}−N_{ab}|≤0.1, the amount of the component (C) could be further adjusted to avoid affecting optical properties. Comparative Example 4 showed that excessive component (C) might lead to reduced light transmittance and poor thermal stability.

Therefore, the composition of the present invention satisfying the condition of |N_{c}−N_{ab}|≤0.1 can achieve the effect of rapid setting or curing, and the resulting product had good optical properties and thermal stability. In some preferred embodiments, the amount of the component (C) may be further adjusted and controlled, so that the resulting product has good optical properties and thermal stability.

What is claimed is:

1. A radiation rapid setting or curing polysiloxane composition, comprising:
(A) an organopolysiloxane having two or more alkenyl groups,
(B) an organohydrogenpolysiloxane having two or more SiH groups,
(C) an organic cross-linking agent having two or more alkenyl groups, and
(D) a photoactive catalyst,
wherein the refractive index (N_{c}) of the component (C) has the following relationship with the refractive index (N_{ab}) of a mixture of the components (A) and (B):

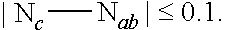

2. The composition of claim 1, wherein the component (A) is represented by the following average formula (I): 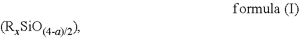
wherein x is a number from 0.8 to 3.0, and
each R is independently a C₂₋₁₂ alkenyl group, a substituted or unsubstituted C₁₋₁₂ alkyl group, a substituted or unsubstituted C₃₋₆ cycloalkyl group, a substituted or unsubstituted C₆₋₂₀ aryl group, or a substituted or unsubstituted C₇₋₂₀ aralkyl group,
wherein at least two R groups in each molecule of the component (A) are C₂₋₁₂ alkenyl groups, and
wherein the component (A) has a weight-average molecular weight of 100 to 100,000.

3. The composition of claim 1, wherein the component (B) is represented by the following average unit formula (III): 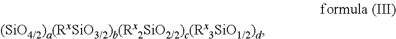
wherein each R^{x} is independently H, a substituted or unsubstituted C₁₋₁₂ alkyl group, a substituted or unsubstituted C₃₋₆ cycloalkyl group, a substituted or unsubstituted C₆₋₂₀ aryl group, or a substituted or unsubstituted C₇₋₂₀ aralkyl group, wherein 0≤a<1, 0≤b<1, 0≤c<1, 0<d<1, a+b+c>0, and a+b+c+d=1,
wherein at least two R^{x} groups in each molecule of the component (B) are H, and
wherein the component (B) has a weight-average molecular weight of 100 to 100,000.

4. The composition of claim 1, wherein based on 100 weight percent of solid ingredients of the composition, the amount of the component (C) is 0.05 weight percent to 10 weight percent.

5. The composition of claim 1, wherein a ratio of the total number of moles of the alkenyl groups in the components (A) and (C) to the total number of moles of the SiH groups in the component (B) ranges from 0.1 to 4.

6. The composition of claim 1, wherein the component (C) is capable of having the following formula: 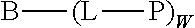
wherein
B serves as a core structure and is a polyvalent organic group with a valence of w;
L is a linking group and is each independently selected from the group consisting of a single bond, —O—, —S—, —C(O)—, —C(O)O—, —OR¹—, —SR¹—, —C(O)R¹— or —C(O)OR¹—;
P is each independently an alkenyl group; and
w is an integer selected from 2 to 8.

7. The composition of claim 6, wherein P is each independently a vinyl group, a propenyl group, an allyl group, an isopropenyl group, a butenyl group, a pentenyl group or a hexenyl group.

8. The composition of claim 6, wherein B is a polyvalent aliphatic hydrocarbon group, a polyvalent aromatic hydrocarbon group, or a polyvalent 3- to 14-membered heterocyclic group having 1 to 3 heteroatoms selected from N, O and S, wherein the polyvalent aliphatic hydrocarbon group or the polyvalent aromatic hydrocarbon group optionally contains one or more oxygen atoms, and wherein the 3- to 14-membered heterocyclic group is optionally substituted with 1 to 3 groups selected from a halogen, a hydroxyl group, an oxo group, an alkyl group and a hydroxyalkyl group.

9. A two-component composition, comprising a combination of component (I) and component (II), wherein
the component (I) comprises the following subcomponents:
(A) an organopolysiloxane having two or more alkenyl groups,
(C) an organic cross-linking agent having two or more alkenyl groups, and
(D) a photoactive catalyst, and
the component (II) comprises the following subcomponent: (B) an organohydrogenpolysiloxane having two or more SiH groups,
wherein the refractive index (N_{c}) of the subcomponent (C) has the following relationship with the refractive index (N_{ab}) of a mixture of the subcomponents (A) and (B):

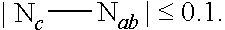

10. A method of manufacturing an encapsulating material, comprising irradiating the composition of claim 1 with a UVA radiation source having an energy of 1,000 to 10,000 mJ/cm² for no more than 10 minutes to set or cure the composition.
